(19) United States
(12) Patent Application Publication
(10) Pub. No.: US 2006/0172518 A1
(43) Pub. Date: Aug. 3, 2006

(54) Method of patterning a layer of a material

(76) Inventors: Kai Frohberg, Meissen (DE); Martin Mazur, Pulsnitz (DE); Harmut Ruelke, Dresden (DE)

Correspondence Address: WILLIAMS, MORGAN & AMERSON, 10333 RICHMOND, SUITE 1100, HOUSTON, TX, 77042, US

(21) Appl. No.: 11/199,445

(22) Filed: Aug. 8, 2005

(30) Foreign Application Priority Data
Jan. 31, 2005 (DE) 10 2005 004 410.7

(51) Int. Cl. H01L 21/4763

(52) U.S. Cl. 438/586; 438/685; 438/725; 438/763

(57) ABSTRACT

The present invention reduces problems resulting from an incomplete removal of photoresist in a photolithographic process which are caused by a diffusion of contaminants from an anti-reflective coating into a layer of photoresist. A protective layer is formed over the anti-reflective coating, and the layer of photoresist is formed over the protective layer. The protective layer substantially prevents a diffusion of contaminants into the photoresist.

### BACKGROUND OF THE INVENTION

1. Field of the Invention

The present invention relates to the formation of integrated circuits, and, more particularly, to the patterning of material layers by means of photolithography.

2. Description of the Related Art

Integrated circuits comprise a large number of individual circuit elements such as, e.g., transistors, capacitors and resistors, formed on a substrate. These elements are connected internally by means of electrically conductive lines to form complex circuits such as memory devices, logic devices and microprocessors. In order to accommodate all the electrically conductive lines required to connect the circuit elements in modern integrated circuits, the electrically conductive lines are arranged in a plurality of levels stacked upon each other over the circuit elements.

The performance of integrated circuits can be improved by increasing the number of functional elements per circuit in order to increase their functionality and/or by increasing the speed of operation of the circuit elements. A reduction of feature sizes allows the formation of a greater number of circuit elements on the same area, hence allowing an extension of the functionality of the circuit, and also reduces signal propagation delays, thus making an increase of the speed of operation of circuit elements possible. In modern integrated circuits, design rules of about 90 nm or less can be applied.

Electrically conductive lines in integrated circuits are frequently made of copper. If, however, copper is incorporated into the crystal lattice of a silicon substrate, deep impurity levels that may degrade the performance of transistors formed in the substrate and cause junction leakage in the transistors can be formed. Even trace amounts of copper in transistors are sufficient to adversely affect the performance of an integrated circuit. Therefore, electrically conductive lines comprising copper are not directly connected to the circuit elements. Instead, plugs comprising a metal other than copper are used to provide electrical contact between the circuit elements and the electrically conductive lines.

A method of providing electrical contact to a circuit element in a semiconductor structure according to the state of the art will now be described with reference to FIGS. 1a-1c. FIG. 1a shows a schematic cross-sectional view of a semiconductor structure 100 in a first stage of the method according to the state of the art. The semiconductor structure 100 comprises a substrate 101 comprising a field effect transistor 150. Shallow trench isolations 102, 103 electrically insulate an active region 104 of the field effect transistor 150 from other circuit elements (not shown). In the active region 104, a source region 109 and a drain region 110 are formed adjacent a gate electrode 105. The gate electrode 105 is flanked by sidewall spacers 107, 108 and separated from the active region 104 by a gate insulation layer 106. Additionally, the substrate 101 comprises a layer 111 of a dielectric material formed on a surface of the substrate 101. The layer 111 covers the field effect transistor 150. The substrate 101 can be formed by means of advanced techniques of deposition, oxidation, ion implantation, etching and photolithography known to persons skilled in the art.

The layer 111 of dielectric material is patterned by means of photolithography, as will be described in the following. On the layer 111 of dielectric material, an anti-reflective coating 112 and a layer 113 of a photoresist are formed. Then, the layer 113 of photoresist is exposed through a reticle (not shown). Portions 113a, 113b, 113c of the layer 113 of photo-resist located over the source 109, the gate electrode 105 and the drain 110 of the field effect transistor 150, respectively, are irradiated with light. Subsequently, a post-exposure bake is performed, wherein the semiconductor structure 100 is exposed to an elevated temperature for a predetermined time. Then, the layer 113 of photoresist is developed. In the development, the irradiated portions 113a, 113b, 113c of the layer 113 of photoresist are dissolved in a developer.

In modern methods of manufacturing semiconductors, frequently so-called chemically amplified photoresists are employed. Chemically amplified photoresists comprise a photo-sensitive compound. If the photosensitive compound is irradiated with light, a catalytically active substance is formed. For example, the catalytically active substance may comprise an acid. The catalytically active substance then catalyzes a cascade of chemical reactions in the photoresist, in particular during the post-exposure bake. Thereby, a structure of the photo-resist is modified in such a way that irradiated portions of the photoresist can be solved in an appropriate developer.

The anti-reflective coating 112 helps avoid adverse effects resulting from an interference between light impinging on the layer 113 of photoresist and light reflected at an inter-face between the layer 113 and the semiconductor structure 100. A thickness of the anti-reflective coating 112 can be adapted such that light reflected from an interface between the anti-reflective coating 112 and the layer 111 of dielectric material interferes destructively with light reflected from an interface between the anti-reflective coating 112 and the layer 113 of photoresist. Additionally, the anti-reflective coating 112 may absorb the light. Thus, a reflection of light and an interference between incident and reflected light can be reduced.

In some examples of methods of providing electrical contact to a circuit element in a semiconductor structure according to the state of the art, the anti-reflective coating 112 comprises compounds comprising nitrogen, for example silicon oxynitride (SiON). Nitrogen contained in the anti-reflective coating 112, however, can diffuse into the layer 113 of photo-resist, in particular into portions close to the interface between the anti-reflective coating 112 and the layer 113. The nitrogen can undergo chemical reactions with components of the photoresist. Products of such reaction may then react with the catalytically active substance generated from the photosensitive compound in the exposure and thus inhibit the catalytic activity thereof, or may react with the photosensitive compound and thus inhibit the creation of the catalytically active substance. Thus, the nitrogen may inhibit the light-induced modification of the photoresist in portions of the layer 113 adjacent the anti-reflective coating 112.

A schematic cross-sectional view of the semiconductor structure 100 in a later stage of the method according to the state of the art is shown in FIG. 1b. After the removal of the portions 113a, 113b, 113c of the layer 113 of photoresist, the layer 113 comprises openings 114, 115, 116 located over the source 109, the gate electrode 105 and the drain 110, respectively, of the field effect transistor 150.

Due to the inhibition of the light-induced modification of the photoresist in portions of the layer 113 adjacent the anti-reflective coating 112, it may occur that residues 117, 118 of the portions 113a, 113b, 113c of the layer 113 of photoresist are not removed in the development process and remain at the bottom of the openings 114, 115, 116.

A schematic cross-sectional view of the semiconductor structure 100 in yet another stage of the method of providing electrical contact to a circuit element in a semiconductor structure according to the state of the art is shown in FIG. 1c.

An anisotropic dry etching process adapted to remove the material of the anti-reflective coating 112 and the material of the layer 111 is performed. In anisotropic etching, an etch rate of substantially horizontal portions of an etched material layer, measured in a direction perpendicular to a surface of the material layer, is significantly greater than an etch rate of inclined portions of the material layer. Hence, portions of the anti-reflective coating 112 and the layer 111 of dielectric material which are not covered by the layer 113 of photo-resist are removed, but substantially no etching of portions of the anti-reflective coating 112 and the layer 111 of dielectric material below the layer 113 of photoresist occurs. Thus, contact vias 119, 120 having sidewalls substantially perpendicular to a surface of the substrate 101 are formed.

The contact vias 119, 120 extend through the anti-reflective coating 112 and the layer 111 of dielectric material. At the bottom of the contact via 119, the source 109 of the field effect transistor 150 is exposed. At the bottom of the contact via 120, the gate electrode 105 is exposed.

The residues 117, 118 of photoresist at the bottom of the openings 115, 116 inhibit the etching of portions of the anti-reflective coating 112 and the layer 111 of dielectric material below the residues 117, 118 of photoresist. Therefore, the presence of the residue 117, which covers a part of the bottom of the opening 115, entails a reduced width of the contact via 120 compared to the contact via 119. The residue 118 which completely covers the bottom of the opening 116, protects portions of the anti-reflective coating 112 and the layer 111 of dielectric material located under the opening 116 from being affected by an etchant used in the dry etching process. Consequently, no contact via is formed below the opening 116.

Finally, the layer 113 of photoresist is removed by means of a resist strip process known to persons skilled in the art, and the contact vias 119, 120 are filled with a metal, for example tungsten. Thus, metal plugs providing electric contact to the source 109 and the gate electrode 105 of the field effect transistor 150 are formed. Since, however, no contact via has been formed below the opening 116, no metal plug providing electric contact to the drain 110 of the field effect transistor 150 is formed. Moreover, the reduced width of the contact via 120 compared to the contact via 119 entails a greater electric resistivity of the metal plug formed in the contact via 120. Both missing metal plugs and metal plugs having a high electric resistivity may adversely affect the functionality of the semiconductor structure 100.

A problem of the method of providing electric contact to a circuit element in a semi-conductor structure according to the state of the art is that, due to the diffusion of nitrogen from the anti-reflective coating 112 into the layer 113 of photoresist, it may occur that irradiated portions of the layer 113 of photoresist are incompletely removed, which can entail a reduced width of contact vias and metal plugs formed in such contact vias, as well as missing contact vias and metal plugs.

In view of the above problem, there is a need for a method of forming a semiconductor structure that more reliably provides electric contact to circuit elements.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to an illustrative embodiment of the present invention, a method of forming a semiconductor structure comprises providing a substrate comprising a layer of a dielectric material formed on a surface of the substrate. An anti-reflective coating is formed over the layer of dielectric material. A protective layer is formed over the anti-reflective coating. A layer of a photoresist is formed over the protective layer.

According to another illustrative embodiment of the present invention, a method of forming a semiconductor structure comprises providing a substrate comprising a field effect transistor. The field effect transistor comprises a source, a drain and a gate electrode. A layer of a dielectric material is formed over the substrate. The layer of dielectric material covers the field effect transistor. An anti-reflective coating is formed over the layer of dielectric material. A protective layer is formed over the anti-reflective coating. At least one contact via is formed through the layer of dielectric material, the anti-reflective coating and the protective layer. The at least one contact via is filled with a metal. The at least one contact via filled with metal provides electrical contact to at least one of the source, the drain and the gate electrode.

According to yet another illustrative embodiment of the present invention, a method of forming a semiconductor structure comprises providing a substrate comprising a layer of a dielectric material formed on a surface of the substrate. An anti-reflective coating is formed over the layer of dielectric material. A protective layer is formed over the anti-reflective coating. The formation of the protective layer comprises plasma enhanced chemical vapor deposition of a silicon dioxide layer. The plasma enhanced chemical vapor deposition comprises providing a reactant gas comprising silane. A layer of a photoresist is formed over the protective layer.

### BRIEF DESCRIPTION OF THE DRAWINGS

The invention may be understood by reference to the following description taken in conjunction with the accompanying drawings, in which like reference numerals identify like elements, and in which:

FIGS. 1a-1c show schematic cross-sectional views of a semiconductor structure in stages of a method of forming a semiconductor structure according to the state of the art;

FIGS. 2a-2c show schematic cross-sectional views of a semiconductor structure in stages of a method of forming a semiconductor structure according to an embodiment of the present invention; and

FIG. 3 shows a schematic cross-sectional view of a reactor adapted for plasma enhanced chemical vapor deposition.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is generally directed to methods of forming a semiconductor structure wherein a layer of photoresist is separated from an anti-reflective coating by a protective layer. The protective layer may be formed by means of plasma enhanced chemical vapor deposition. The protective layer can prevent a diffusion of contaminants such as nitrogen from the anti-reflective coating into the layer of photoresist. Thus, adverse effects of the diffusion of contaminants into the photoresist such as an inhibition of the light-induced modification of the photoresist can be substantially avoided.

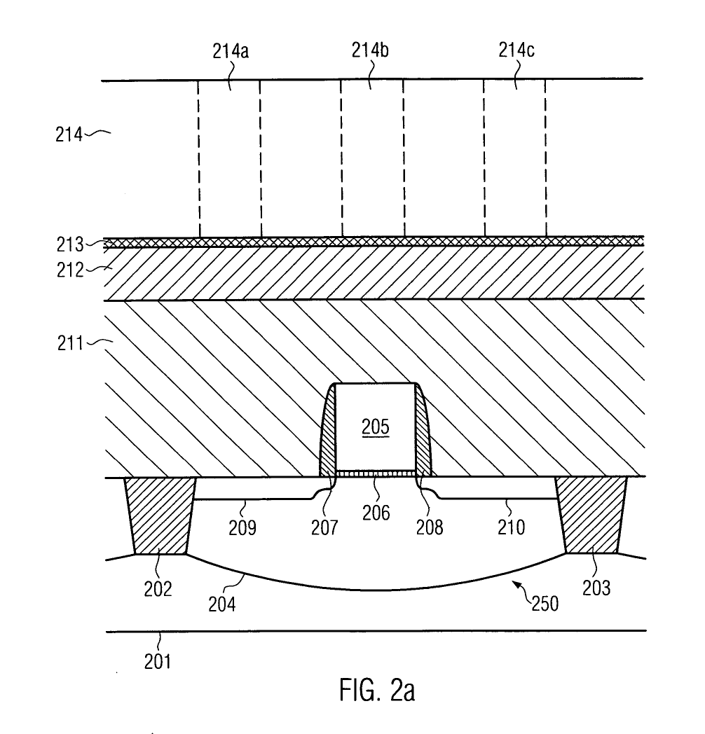

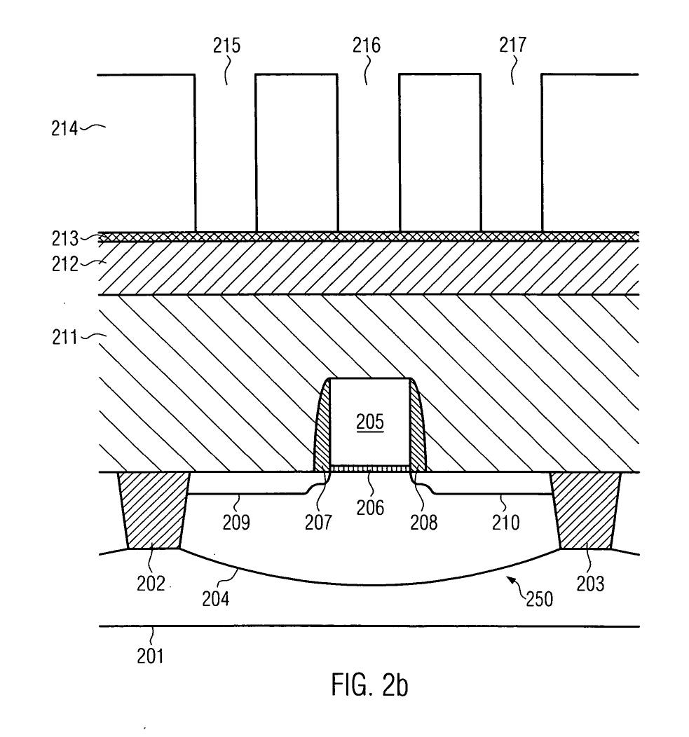

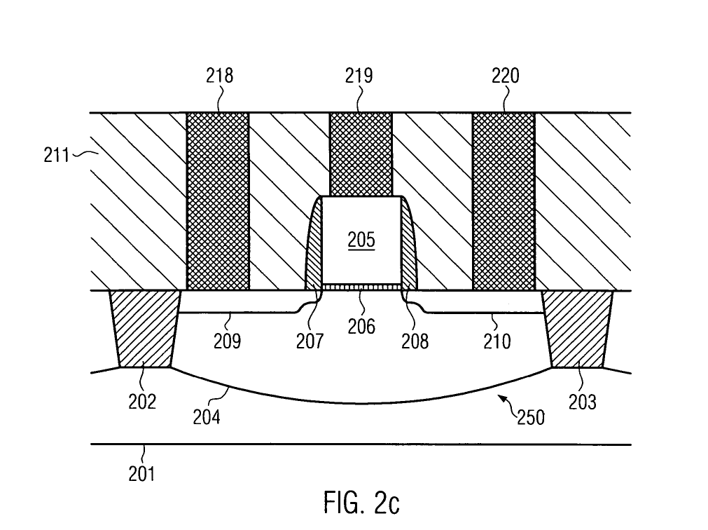

Further embodiments of the present invention will now be described with reference to FIGS. 2a-2c. FIG. 2a shows a schematic cross-sectional view of a semiconductor structure 200 in a first stage of a method of forming a semiconductor structure according to an embodiment of the present invention. The semiconductor structure 200 comprises a field effect transistor 250 formed in a substrate 201. Shallow trench isolations 202, 203 electrically insulate the filed effect transistor 250 from other circuit elements in the substrate 201. The field effect transistor 250 comprises an active region 204. In the active region 204, a source 209 and a drain 210 are formed. A gate electrode 205 is formed over the active region 204 and separated therefrom by a gate insulation layer 206. Sidewall spacers 207, 208 are formed adjacent the gate electrode 205.

Additionally, the substrate 201 comprises a layer 211 of a dielectric material formed on a surface of the substrate 201. The layer 211 of dielectric material can cover the field effect transistor 250, and may additionally cover other circuit elements (not shown) formed in the substrate 201. The dielectric material can comprise silicon dioxide (SiO₂) or silicon nitride (Si₃N₄). The substrate 201 can be formed by means of advanced techniques of deposition, oxidation, ion implantation, etching and photolithography known to persons skilled in the art.

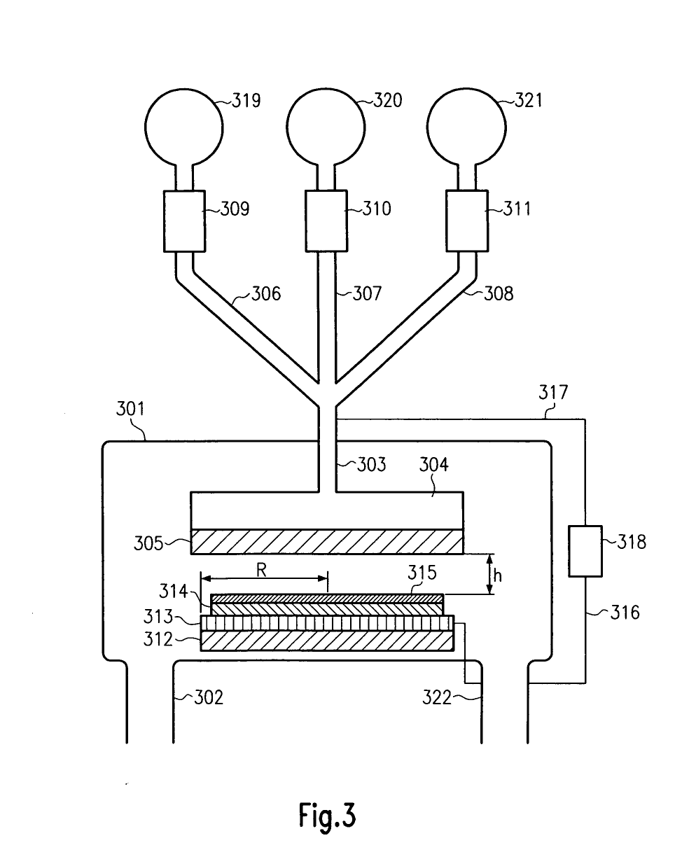

An anti-reflective coating 212 is formed over the layer 211 of interlayer dielectric. The anti-reflective coating 212 can comprise silicon oxynitride (SiON). Over the anti-reflective coating 212, a protective layer 213 is formed. The protective layer 213 can comprise silicon dioxide (SiO₂). The anti-reflective coating 212 and the protective layer 213 can be formed by means of plasma enhanced chemical vapor deposition. Plasma enhanced chemical vapor deposition will now be described with reference to FIG. 3, showing a schematic cross-sectional view of a reactor 300 for plasma enhanced chemical vapor deposition.

The reactor 300 comprises a vessel 301. In the vessel 301, a substrate 314 is provided over an electrode 313 and a heater 312. The heater has a radius R and is adapted to maintain the substrate 314 at a predetermined temperature. The radius R can be about the same as a radius of the substrate 314 or greater. A showerhead 303 is provided above the substrate 314 and the electrode 313. A spacing h separates the showerhead 303 from the substrate 314. In one particular embodiment of the present invention, the radius R may have a value of about 100 mm and the vessel 301 may have a volume in a range from about 11000-13000 cm³. The spacing h may be varied, e.g., by moving the showerhead 303 or the substrate 314. The showerhead 303 and the electrode 313 are connected to a power source 318 by means of wires 316, 317.

The showerhead 303 comprises a plenum 304. Lines 306, 307, 308 connect the plenum 304 to gas sources 319, 320, 321. Each of the gas sources 319, 320, 321 can be adapted to provide a gas of a particular species. In particular, the gases provided by gas sources 319, 320, 321 may comprise gaseous reactants and/or background gases provided for diluting the reactants. Mass flow controllers 309, 310, 311 are adapted to regulate a gas flow from the gas sources 319, 320, 321 to the plenum 304. A distribution plate 305 separates the plenum 304 from an inner volume of the vessel 301. The distribution plate 305 is gas permeable and may comprise channels and/or pores (not shown) through which the reactants can flow from the plenum 304 to the inner volume of the vessel 301.

The reactor 300 need not comprise three gas sources. In other embodiments of the present invention, a greater or smaller number of gas sources connected to the plenum 304 may be provided, depending on the number of different gases used in the plasma enhanced chemical vapor deposition process. In order to control gas flow from the gas sources to the reactor vessel 301, each of the gas sources can be equipped with a mass flow controller similar to the mass flow controllers 309, 310, 311.

The power source 318 can be adapted to apply a radio frequency alternating voltage between the showerhead 303 and the electrode 313. Additionally, the power source 318 may be adapted to apply a direct voltage or a low frequency alternating voltage which is denoted as “bias voltage” between the showerhead 303 and the electrode 313. In other embodiments of the present invention, the reactor 300 may comprise two separate power sources adapted to provide the radio frequency alternating voltage and the bias voltage, respectively.

Gases may leave the vessel 301 through exhaust ports 302, 322. The exhaust ports 302, 322 may be connected to vacuum pumps (not shown) which are adapted to control a pressure in the vessel 301.

In the operation of the reactor 301, a first gas flows from the gas source 319 to the plenum 304. The flow of the first gas is controlled by mass flow controller 309. Similarly, a second gas and a third gas flow from the gas source 320 and the gas source 321, respectively, to the plenum 304. The flow of the second and the third gas is controlled by mass flow controllers 310 and 311, respectively. A greater or smaller number of gases may be flown to the plenum by means of a greater or smaller number of gas sources connected to the plenum and a corresponding number of mass flow controllers, as detailed above.

In the plenum 304, the gases mix with each other. The gas mixture flows through the distribution plate 305 into the vessel 301. A flow direction of the gas mixture is directed towards the substrate 314. The radio frequency alternating voltage and/or the bias voltage applied between the showerhead 303 and the electrode 313 induce a glow discharge in a volume between the showerhead 303 and the substrate 314. Due to the glow discharge, a plasma is created from the gas mixture. The plasma comprises species such as, e.g., ions, radicals and atoms and molecules, respectively, in excited states having a high reactivity. As the flow of the gas mixture and/or the plasma approaches the substrate 314, it is deflected from its flow direction and obtains a radial velocity directed towards a circumference of the substrate 314.

On the substrate 314, or in the vicinity thereof, a chemical reaction occurs between the gaseous reactants and/or species created therefrom in the plasma. Solid products of the chemical reaction are deposited on the substrate 314 and form a material layer 315 on a deposition surface thereof. Gaseous products of the chemical reaction, unconsumed reactants and background gases leave the vessel 301 through exhaust ports 302, 322.

The properties of the plasma enhanced chemical vapor deposition process and the material layer 315 created thereby are influenced by parameters such as the kind of reactants used, the flows of the individual reactants, the spacing h, the temperature of the substrate, the power of the radio frequency alternating voltage and the bias voltage.

Changing the spacing h alters the volume of the plasma, and hence the surface-to-volume ratio between an area of the deposition surface of the substrate 314 and the volume of the plasma. This may affect a residence time of particles in the plasma, a consumption rate of the reactants, and the radial velocities of gases flowing over the substrate. Thus, the extent of gas phase reactions, characteristics of the gas flow and a radial uniformity of the deposited material layer 315 can be influenced. Additionally, changes of the spacing h may have effects on density and potential of the plasma. The density of the plasma can also be controlled by varying the power of the radio frequency alternating voltage and/or the pressure in the vessel 301. Variations of the bias voltage may alter the velocity at which ions, which are accelerated in the electric field generated by the bias voltage, impinge on the substrate 314. The temperature of the substrate 314 may affect the rate of chemical reactions occurring on the deposition surface. A thickness of the deposited material layer may be controlled by varying the time during which the plasma enhanced deposition process is performed. A longer deposition time yields a greater thickness of the material layer 315.

A plasma enhanced chemical vapor deposition process may be performed by means of reactors of different size. This may require an adaptation of some of the parameters of the deposition process. For example, gas flows may be scaled in relation to the volume of the vessel 301, wherein ratios between the gas flows are maintained. A power of the radio frequency alternating voltage may be scaled in relation to an area of the surface of the substrate 314.

In the formation of the anti-reflective coating 212 and the protective layer 213, the semiconductor structure 201 can be provided as the substrate 314 in the reactor 300. The deposition surface may comprise surfaces of the layer 211 of dielectric material and the anti-reflective coating 212, respectively.

A variation of the above-mentioned parameters in the formation of the anti-reflective coating 212 may have an influence on an index of refraction and an absorption coefficient of the anti-reflective coating 212.

In the formation of the protective layer 213, the above-mentioned parameters can influence a permeability of the protective layer 213 for contaminants such as nitrogen.

In embodiments of the present invention wherein the anti-reflective coating 212 comprises silicon oxynitride, in the formation of the anti-reflective coating, gas flows comprising silane (SiH₄), nitrous oxide (N₂O) and, optionally, ammonia (NH₃) may be supplied as reactants into the plenum 304 of the showerhead 303. Additionally, a diluent comprising nitrogen (N₂) and/or a noble gas such as helium (He), neon (Ne), argon (Ar), krypton (Kr) or xenon (Xe) can be flowed into the plenum 304.

In one embodiment of the present invention, in the formation of the anti-reflective coating 212, a silane flow in a range from about 100-500 sccm, for example a silane flow of about 240 sccm, a nitrous oxide flow in a range from about 20-200 sccm, for example a nitrous oxide flow of about 45 sccm, and a nitrogen flow in a range from about 1000-5000 sccm, for example a nitrogen flow of about 1500 sccm are provided. The pressure in the vessel 301 is controlled to be in a range from about 1.5-5.0 Torr. For example, the pressure can be about 3.3 Torr. The heater 312 is controlled to maintain the temperature of the semi-conductor structure 200 within a range from about 300-450° C., for example at about 400° C. The spacing h is maintained in a range from about 200-500 mils, for example at about 280 mils. The radio frequency alternating voltage has a power in a range from about 100-500 W, for example a power of about 350 W.

In other embodiments, the gas flows and the power of the radio frequency alternating voltage may be scaled in relation to the size of the reactor 300 and the semiconductor structure 200, as detailed above. A ratio between the silane flow and the volume of the vessel 301 may have a value in a range from about 0.0077-0.045 sccm/cm³, for example a value of about 0.02 sccm/cm³. A ratio between the nitrous oxide flow and the volume of the vessel 301 can have a value in a range from about 0.0015-0.018 sccm/cm³, for example a value of about 0.0038 sccm/cm³, and a ratio between the nitrogen flow and the volume of the vessel 301 can have a value in a range from about 0.077-0.45 sccm/cm³, for example a value of about 0.13 sccm/cm³. A ratio between the power of the radio frequency alternating voltage and an area of the surface of the semiconductor structure 200 can have a value in a range from about 0.32-1.59 W/cm², for example a value of about 1.11 W/cm².

The anti-reflective coating 212 can have a thickness in a range from about 300-800 Å, for example a thickness of about 500 Å. In order to provide a thickness of the anti-reflective coating 212 of about 500 Å, the above-described deposition process can be performed for about 4.7-5.7 seconds, for example for about 5.2 seconds. Other values of the thickness of the anti-reflective coating 212 can be obtained by scaling the duration of the deposition process accordingly, as persons skilled in the art know.

In embodiments of the present invention wherein the protective layer 213 comprises silicon dioxide, the formation of the protective layer 213 can comprise supplying gas flows comprising silane (SiH₄) and an oxidant comprising at least one of oxygen (O₂), nitrous oxide (N₂O) and ozone (O₃). Additionally, a diluent gas can be supplied. While, in some embodiments of the present invention, the diluent gas may comprise nitrogen (N₂), in other embodiments of the present invention, the diluent gas can comprise a noble gas. Advantageously, providing a diluent gas comprising a noble gas helps avoid an incorporation of nitrogen into the protective layer 213 which might adversely affect a patterning of layers of the semiconductor structure 200 by means of photolithography. In other embodiments of the present invention, no diluent gas is supplied.

In one embodiment of the present invention, in the formation of the protective layer 213, a silane flow in a range from about 50-300 sccm, for example a silane flow of about 100 sccm, and a nitrous oxide flow in a range from about 2000-8000 sccm, for example a nitrous oxide flow of about 4000 sccm, are provided. The pressure in the vessel 301 is controlled to be in a range from about 1.5-5.0 Torr. For example, the pressure can be about 3.0 Torr. The heater 312 is controlled to maintain the temperature of the semiconductor structure 200 in a range from about 300-450° C., for example at about 400° C. The spacing h has a value in a range from about 300-600 mils, for example a value of about 480 mils, and a power of the radio frequency alternating voltage is controlled to be in a range from about 100-500 W, for example at about 270 W. The bias voltage can be about zero.

In some embodiments, a ratio between the silane flow and the volume of the vessel 301 has a value in a range from about 0.0038-0.027 sccm/cm³, for example a value of about 0.0083 sccm/cm³. A ratio between the nitrous oxide flow and the volume of the vessel 301 has a value in a range from about 0.15-0.72 sccm/cm³, for example a value of about 0.33 sccm/cm³. A ratio between the power of the radio frequency alternating voltage and the area of the surface of the semiconductor structure 200 has a value in a range from about 0.32-1.59 W/cm², for example a value of about 0.86 W/cm².

Both the formation of the anti-reflective coating 212 and the formation of the protective layer 213 can be performed in an Applied Materials Producer dual chamber/single wafer PECVD system known to persons skilled in the art.

In some embodiments of the present invention, a moderately abrupt transition between the anti-reflective coating 212 and the protective layer 213 may be provided.

In particular embodiments of the present invention, the formation of the protective layer 213 can be performed in situ in the same reactor as the formation of the anti-reflective coating 212. In such embodiments, after the formation of the anti-reflective coating 212, a moderately abrupt switching from parameters of the plasma enhanced chemical vapor deposition process applied in the formation of the anti-reflective coating 212 to parameters applied in the formation of the protective layer 213 can be performed.

A purging of the reaction vessel 301 can be performed between the formation of the anti-reflective coating 212 and the formation of the protective layer 213. To this end, after the formation of the anti-reflective coating 212, the power source 318 is turned off. Thus, there is no glow discharge in the reactor 300 any more, and substantially no deposition of material on the semiconductor structure 200 occurs. Then, flows of reactant gases substantially identical to those used in the formation of the protective layer 213 are supplied to the vessel 301 for a predetermined time. The predetermined time is adapted such that residues of reactant gases used in the formation of the anti-reflective coating 212 are substantially flushed out of the vessel 301 and may have a duration in a range from about 15-40 seconds. After the purging, the power source 318 is turned on, and the protective layer 213 is formed.

In further embodiments of the present invention, a moderately abrupt transition between the anti-reflective coating 212 and the protective layer 213 can be obtained by performing the formation of the anti-reflective coating 212 and the formation of the protective layer 213 in different reactors.

In other embodiments of the present invention, a smooth transition between the anti-reflective coating 212 and the protective layer 213 is provided. To this end, the formation of the protective layer 213 can be performed in situ in the same reactor as the formation of the anti-reflective coating 212. After the formation of the anti-reflective coating 212, the power source 308 is activated while the parameters of the deposition process are changed from those applied in the formation of the anti-reflective coating 212 to those applied in the formation of the protective layer 213.

The protective layer 213 may have a thickness in a range from about 50-300 Å, for example a thickness of about 80 Å. A thickness of the protective layer 213 of about 80 Å can be obtained by performing the above-described deposition process for about 1.5-1.9 seconds, for example for about 1.7 seconds. A thickness of the protective layer 213 of about 200 Å can be obtained by performing the above deposition process for about 4.0-4.8 seconds, for example for about 4.4 seconds.

After the formation of the protective layer 213, a layer 214 of a photoresist is formed over the protective layer. This can be done by means of methods known to persons skilled in the art comprising spin coating. Subsequently, portions 214a, 214b, 214c of the layer 214 of photoresist are irradiated with light, which can be done by exposing the layer 214 of photo-resist through a reticle. In some embodiments of the present invention, the light may have a wavelength of about 193 nm or less.

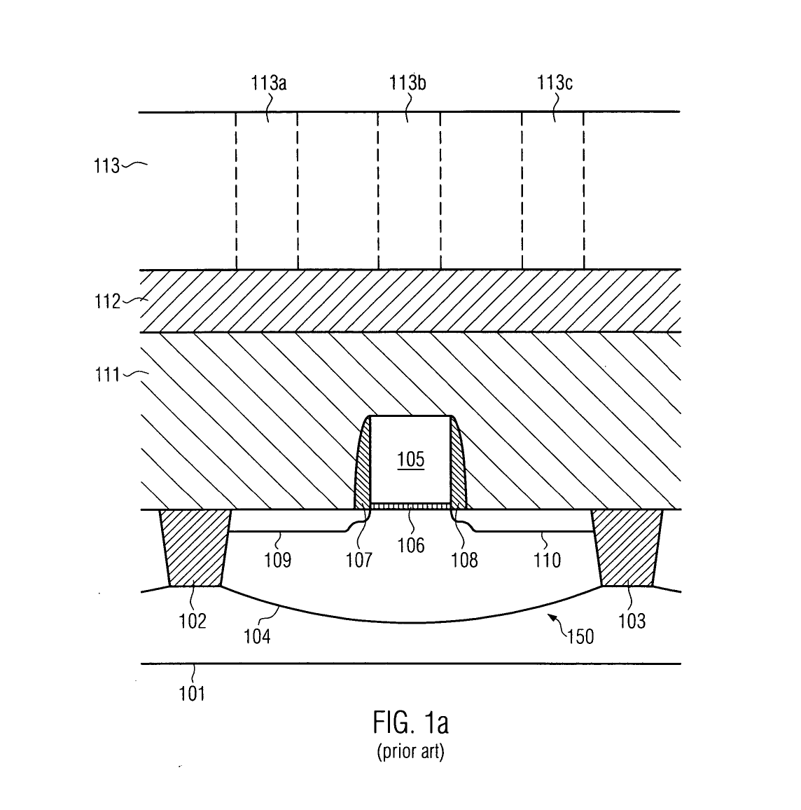

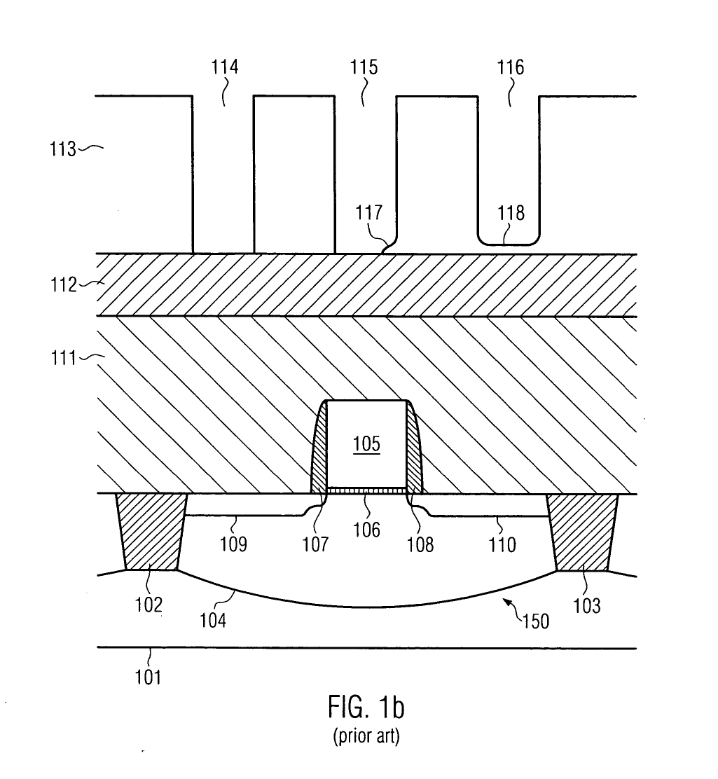

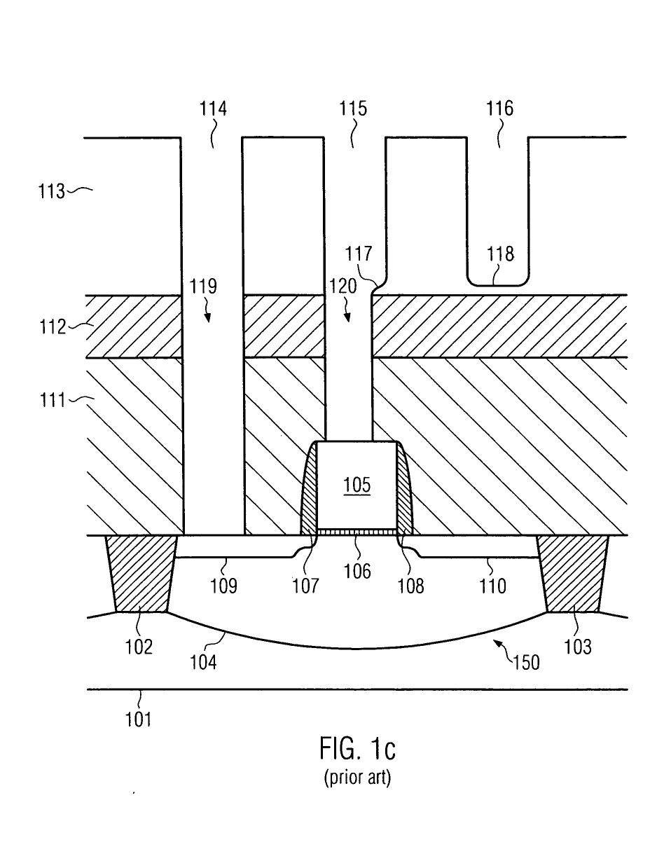

Similar to the layer 113 of photoresist used in the method according to the state of the art described above with reference to FIGS. 1a-1c, the layer 214 of photoresist can comprise a chemically amplified photoresist comprising a photosensitive compound creating a catalytically active substance when irradiated with light. The catalytically active substance can catalyze a cascade of chemical reactions leading to a modification of a structure of the photo-resist. The catalytically active substance may comprise an acid. The chemically amplified photoresist can be susceptible to an inhibition of a light-induced modification induced by the presence of contaminants such as nitrogen.

The protective layer 213 provides a barrier substantially preventing a diffusion of contaminants such as nitrogen from the anti-reflective coating 212 or the layer 111 of dielectric material into the layer 214 of photoresist. Therefore, substantially no inhibition of light-induced modifications of the photoresist in the layer 214 induced by contaminants stemming from the anti-reflective coating 212 occurs, and substantially all of the photoresist in portions 214a, 214b, 214c is modified due to the irradiation with light.

After the exposure of the layer 214 of photoresist, a post-exposure bake wherein the semiconductor structure 200 is exposed to an elevated temperature for a predetermined time can be performed. The post-exposure bake may assist the catalytic activity of the catalytically active substance.

A schematic cross-sectional view of the semiconductor structure 200 in a later stage of a method of forming a semiconductor structure according to the present invention is shown in FIG. 2b. The layer 214 of photoresist is developed. In the development process, the irradiated portions 214a, 214b, 214c of the layer 214 of photoresist are solved in a developer to form openings 215, 216, 217 extending through the layer 214 of photoresist. Since, due to the presence of the protective layer 213, all of the photoresist in portions 214a, 214b, 214c has been modified, portions 214a, 214b, 214c are substantially completely removed and substantially no residues of photoresist remain at the bottom of the openings.

At the bottom of the opening 215, a portion of the protective layer 213 located above the source 209 of the field effect transistor 250 is exposed. Similarly, portions of the protective layer 213 located above the gate electrode 205 and the drain 210 are exposed at the bottom of the opening 216 and the bottom of the opening 217, respectively.

FIG. 2c shows a schematic cross-sectional view of the semiconductor structure 200 in yet another stage of the method of forming a semiconductor structure according to the present invention. After the development of the photoresist in the layer 214, contact vias 218, 219, 220 are formed through the protective layer 213, the anti-reflective coating 212 and the layer 211 of dielectric material. Similar to the formation of the contact vias 119, 120 in the method of providing electrical contact to a circuit element in a semiconductor structure described above with reference to FIGS. 1a-1c, this can be done by means of an anisotropic etch process.

In the anisotropic etch process, the semiconductor structure 200 is exposed to at least one gaseous etchant adapted to remove materials of the protective layer 213, the anti-reflective coating 212 and the layer 211 of dielectric material. In some embodiments of the present invention, a composition of the gaseous etchant may be varied in the course of the etch process in order to remove the different materials in the protective layer 213, the anti-reflective coating 212 and the layer 211. In other embodiments, a single etchant adapted to remove each of the materials of the layer 211, the anti-reflective coating 212 and the protective layer 213 can be used.

The anisotropic etch process is stopped as soon as the source 209, the gate electrode 205 and the drain 210 of the field effect transistor 250 are exposed at the bottom of the contact vias 218, 219, 220. This can be done by means of an etch stop layer (not shown) provided between the field effect transistor 250 and the layer 211 of dielectric material. The etch stop layer may comprise a material substantially not being affected by the at least one etchant used in the anisotropic etching process, thus protecting the source 209, the gate electrode 205 and the drain 210 from being affected by the at least one etchant. Additionally, the etch stop layer may provide an indication when an etch front has passed the layer 211 of dielectric material. After the anisotropic etch process, the layer 214 of photoresist can be removed, which may be done by means of conventional resist strip processes known to persons skilled in the art.

After the formation of the contact vias 218, 219, 220, a metal layer can be deposited over the semiconductor structure 201. This may be done by means of known methods comprising plasma enhanced chemical vapor deposition, sputtering and/or electroplating. In some embodiments of the present invention, the metal layer may comprise tungsten. In the formation of the metal layer, the contact vias 218, 219, 220 are filled with metal. Between the semiconductor structure 201 and the metal layer, a barrier layer comprising titanium nitride (TiN), titanium (Ti) and/or tungsten nitride (WN) can be provided.

Thereafter, the surface of the semiconductor structure 200 may be planarized, which can be done by means of chemical mechanical polishing. Chemical mechanical polishing comprises moving the semiconductor structure 200 relative to a polishing pad. Slurry is supplied to an interface between the semiconductor structure 200 and the polishing pad. The slurry comprises a chemical compound reacting with the material or materials on the surface of the semiconductor structure 200. The reaction product is removed by abrasives contained in the slurry and/or the polishing pad.

In the chemical mechanical polishing process, portions of the metal layer outside the contact vias 218, 219, 220 are removed. Additionally, the chemical mechanical polishing process may remove the protective layer 213 and the anti-reflective coating 212.

After the chemical mechanical polishing, the contact vias 218, 219, 220 comprise metal plugs providing electrical contact to the source 209, the gate electrode 205 and the drain 210 of the field effect transistor. Since, in a method according to the present invention, an incomplete removal of photoresist from the bottom of the openings 215, 216, 217 may substantially be avoided, problems resulting from metal plugs having a reduced width and missing metal plugs can be reduced. Therefore, the present invention allows more reliable electric contact to circuit elements in a semiconductor structure.

The present invention is not restricted to the formation of metal plugs providing electric contact to circuit elements such as field effect transistors, as described above. In other embodiments of the present invention, a protective layer adapted to prevent a diffusion of contaminants into a layer of photoresist may as well be applied in the formation of contact vias which, when filled with a metal such as copper (Cu) or tungsten (W), which can be deposited over a barrier layer comprising tantalum nitride (TaN), titanium nitride (TiN), titanium (Ti) and/or tungsten nitride (WN), provide electrical contact between electrically conductive lines in higher interconnect levels.

In further embodiments, the present invention is applied to the photolithographic formation of structural features other than contact vias. For example, a protective layer between an anti-reflective coating and a layer of photoresist according to the present invention may be provided in the formations of trenches which are subsequently filled with metal to form electrically conductive lines. The present invention may also be applied, e.g., in the photolithographic formation of gate electrodes of field effect transistors and/or in the formation of shallow trench isolations electrically insulating circuit elements in an integrated circuit from each other.

The present invention is not restricted to embodiments wherein openings in a layer of photoresist are formed by removing portions of the layer photoresist which were irradiated with light in the exposure. In other embodiments of the present invention, a negative photo-resist is applied. In negative photoresists, portions of a layer of photoresist which were not irradiated with light are soluble in a developer. Hence, openings in a layer of a negative photoresist can be formed by removing non-irradiated portions of the layer of negative photo-resist in the development process.

Negative photoresists can be chemically amplified photoresists comprising a photo-sensitive compound adapted to undergo a chemical reaction wherein a catalytically active substance is produced when the photoresist is irradiated with light. The catalytically active substance then catalyzes a cascade of chemical reactions leading to a modification of the structure of the photoresist. If the photosensitive compound and/or the catalytically active substance are blocked by contaminants comprising, e.g., nitrogen, and diffusing into the photoresist from an anti-reflective coating located under the layer of photoresist, the modification of the photoresist may be inhibited in portions of the photoresist adjacent the anti-reflective coating. In the development of the photoresist, it may occur that such portions are removed, which may lead to an undesirable flaking off of photoresist located above such portions.

In embodiments of the present invention wherein a negative photoresist is applied, a protective layer similar to the protective layer 213 in the embodiments described above with reference to FIGS. 2a-2c is formed over an anti-reflective coating. Then, a layer of the negative photoresist is formed over the protective layer. The layer of negative photoresist is then exposed, and the non-irradiated portions of the layer of negative photoresist are solved in a developer. The protective layer prevents a diffusion of contaminants from the anti-reflective coating into the layer of negative photoresist. Thus, a flaking off of portions of the photoresist may advantageously be reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a semiconductor structure, comprising:
providing a substrate comprising a layer of a dielectric material formed on a surface of said substrate;
forming an anti-reflective coating over said layer of dielectric material;
forming a protective layer over said anti-reflective coating; and
forming a layer of a photoresist over said protective layer.

2. The method of claim 1, wherein said substrate comprises a field effect transistor and said layer of dielectric material covers said field effect transistor.

3. The method of claim 2, further comprising:
irradiating at least one portion of said layer of photoresist located over at least one of a source, a drain and a gate electrode of said field effect transistor with light; and
solving said irradiated portion in a developer.

4. The method of claim 3, wherein said light has a wavelength of about 193 nm or less.

5. The method of claim 3, further comprising:
forming at least one contact via through said protective layer, said anti-reflective coating and said layer of dielectric material; and
filling said at least one contact via with a metal, said at least one contact via filled with metal providing electrical contact to said at least one of the source, the drain and the gate electrode of said field effect transistor.

6. The method of claim 5, wherein said metal comprises tungsten.

7. The method of claim 1, wherein said anti-reflective coating comprises nitrogen.

8. The method of claim 1, wherein said protective layer has a thickness in a range from about 50-300 Å.

9. The method of claim 1, wherein said protective layer comprises silicon dioxide.

10. The method of claim 1, wherein said formation of said protective layer comprises plasma enhanced chemical vapor deposition.

11. The method of claim 10, wherein said plasma enhanced chemical vapor deposition comprises providing a reactant gas comprising silane (SiH₄).

12. The method of claim 1, wherein said photoresist comprises a component susceptible to undergo a chemical reaction with a component of said anti-reflective coating.

13. The method of claim 10, wherein at least one of a photosensitive component of said photoresist and a catalytically active substance created from said photosensitive component under an influence of light is susceptible to being blocked owing to said chemical reaction.

14. The method of claim 1, wherein said protective layer is formed on said anti-reflective coating.

15. A method of forming a semiconductor structure, comprising:
providing a substrate comprising a field effect transistor, said field effect transistor comprising a source, a drain and a gate electrode;
forming a layer of a dielectric material over said substrate, said layer of dielectric material covering said field effect transistor;
forming an anti-reflective coating over said layer of dielectric material;
forming a protective layer over said anti-reflective coating;
forming at least one contact via through said layer of dielectric material, said anti-reflective coating and said protective layer; and
filling said at least one contact via with a metal, said at least one contact via filled with metal providing electrical contact to at least one of said source, said drain and said gate electrode.

16. The method of claim 15, wherein said metal comprises tungsten.

17. The method of claim 15, wherein said protective layer comprises silicon dioxide.

18. The method of claim 15, wherein said formation of said protective layer comprises plasma enhanced chemical vapor deposition.

19. The method of claim 18, wherein said plasma enhanced chemical vapor deposition comprises providing a reactant gas comprising silane.

20. The method of claim 15, wherein said protective layer has a thickness in a range from about 50-300 Å.

21. The method of claim 15, wherein forming said at least one contact via comprises irradiating a layer of photoresist formed above said protective layer with light, said light having a wavelength of about 193 nm or less.

22. The method of claim 15, wherein said anti-reflective coating comprises nitrogen.

23. The method of claim 15, wherein forming said at least one contact via comprises irradiating a layer of photoresist formed above said protective layer with light, said layer of photoresist comprising a component susceptible to undergo a chemical reaction with a component of said anti-reflective coating.

24. The method of claim 23, wherein at least one of a photosensitive component of said layer of photoresist and a catalytically active substance created from said photo-sensitive component under an influence of light is susceptible to being blocked owing to said chemical reaction.

25. The method of claim 13, wherein said protective layer is formed on said anti-reflective coating.

26. A method of forming a semiconductor structure, comprising:
providing a substrate comprising a layer of a dielectric material formed on a surface of said substrate;
forming an anti-reflective coating over said layer of dielectric material;
forming a protective layer over said anti-reflective coating, wherein said formation of said protective layer comprises plasma-enhanced chemical vapor deposition of a silicon dioxide layer, said plasma-enhanced chemical vapor deposition comprising providing a reactant gas comprising silane (SiH₄); and
forming a layer of a photoresist over said protective layer.

27. The method of claim 26, wherein said substrate comprises a field effect transistor and said layer of dielectric material covers said field effect transistor.

28. The method of claim 27, further comprising:
irradiating at least one portion of said layer of photoresist located over at least one of a source, a drain and a gate electrode of said field effect transistor with light; and
dissolving said irradiated portion in a developer.

29. The method of claim 28, further comprising:
forming at least one contact via through said protective layer, said anti-reflective coating and said layer of dielectric material; and
filling said at least one contact via with a metal, said at least one contact via filled with metal providing electrical contact to said at least one of the source, the drain and the gate electrode of said field effect transistor.
